(19) United States
(12) Patent Application Publication
(10) Pub. No.: US 2015/0132908 A1
(43) Pub. Date: May 14, 2015

(54) METHOD FOR FABRICATING SEMICONDUCTOR DEVICE

(71) Applicant: Samsung Electronics Co., Ltd., Suwon-si (KR)

(72) Inventors: Yeong-Jong Jeong, Yongin-si (KR); Jeong-Yun Lee, Yongin-si (KR); Shi Ii Quan, Suwon-si (KR); Sug-Hyun Sung, Yongin-si (KR)

(73) Assignee: Samsung Electronics Co., Ltd., Suwon-si (KR)

(21) Appl. No.: 14/294,429

(22) Filed: Jun. 3, 2014

(30) Foreign Application Priority Data
Nov. 12, 2013 (KR) 10-2013-0136997

(51) Int. Cl. H01L 29/66; H01L 21/02

(52) U.S. Cl. CPC H01L 29/66545; H01L 29/66795; H01L 21/02639
USPC 438/283

(57) ABSTRACT

A semiconductor device and method of fabricating the device, includes forming a fin-type active pattern that projects above a field insulating layer and forming a dummy gate structure that includes an epitaxial growth prevention layer to suppress nodule formation.

### CROSS-REFERENCE TO RELATED APPLICATIONS

This application is based on and claims priority from Korean Patent Application No. 10-2013-0136997, filed on Nov. 12, 2013 in the Korean Intellectual Property Office, the disclosure of which is incorporated herein in its entirety by reference.

### BACKGROUND

1. Field of the Invention

Inventive concepts relate to a method for fabricating a semiconductor device.

2. Description of the Prior Art

A multi-gate transistor, in which a fin-type silicon body is formed on a substrate and a gate is formed on a surface of the silicon body, has been proposed as a method of increasing the density of semiconductor devices.

Because a multi-gate transistor may use a three-dimensional (3D) channel, scaling can performed and current control capability may be improved even without increasing a gate length of the multi-gate transistor. In addition, a short channel effect (SCE), in which an electric potential of a channel region is affected by a drain voltage, can be effectively suppressed.

### SUMMARY

In exemplary embodiments in accordance with principles of inventive concepts, a method for fabricating a semiconductor device may include forming a fin-type active pattern that projects above a field insulating layer; forming a dummy gate structure, which includes a dummy silicon oxide layer, an epitaxial growth prevention layer, and a hard mask, that are sequentially stacked, and which crosses the fin-type active pattern, on the fin-type active pattern; forming a recess in the fin-type active pattern at each side of the dummy gate structure; forming a semiconductor pattern in the recess using epitaxial growth; forming a trench, which crosses the fin-type active pattern, on the fin-type active pattern by removing the dummy gate structure; and forming a replacement metal gate in the trench, wherein the epitaxial growth prevention layer has high growth selectivity with respect to the epitaxial growth, so that the semiconductor pattern is not grown other than in the recess.

In exemplary embodiments in accordance with principles of inventive concepts, a method for fabricating a semiconductor device may include a dummy gate structure further includes a poly silicon layer between the dummy silicon oxide layer and the epitaxial growth prevention layer.

In exemplary embodiments in accordance with principles of inventive concepts, a method for fabricating a semiconductor device may include the distance between the field insulating layer and an upper surface of the fin-type active pattern is less than the distance between the field insulating layer and an upper surface of the poly silicon layer.

In exemplary embodiments in accordance with principles of inventive concepts, a method for fabricating a semiconductor device may include a dummy gate structure further includes a polishing stopper layer between the poly silicon layer and the epitaxial growth prevention layer.

In exemplary embodiments in accordance with principles of inventive concepts, a method for fabricating a semiconductor device may include a polishing stopper layer includes at least one of silicon nitride, hafnium oxide (Fox), aluminum oxide (AlOx), titanium oxide (TiOX), and aluminum nitride (AlN).

In exemplary embodiments in accordance with principles of inventive concepts, a method for fabricating a semiconductor device may include an epitaxial growth prevention layer includes at least one of silicon oxide, hafnium oxide (HfOx), aluminum oxide (AlOx), BACL (Boron doped Amorphous Carbon Layer), titanium nitride (TiN), titanium oxide (TiOx), aluminum nitride (AlN), and chrome (Cr).

In exemplary embodiments in accordance with principles of inventive concepts, a method for fabricating a semiconductor device may include a dummy gate structure further includes a barrier layer between the dummy silicon oxide layer and the epitaxial growth prevention layer, and wherein the barrier layer includes a material having etching selectivity with respect to the epitaxial growth prevention layer.

In exemplary embodiments in accordance with principles of inventive concepts, a method for fabricating a semiconductor device may include a barrier layer is formed to come in contact with the dummy silicon oxide layer and the epitaxial growth prevention layer.

In exemplary embodiments in accordance with principles of inventive concepts, a method for fabricating a semiconductor device may include forming a gate spacer, which includes a material that is different from a material of the hard mask, on the side surface of the dummy gate structure while the recess is formed, wherein the hard mask includes an etch resistant material as compared with the gate spacer.

In exemplary embodiments in accordance with principles of inventive concepts, a method for fabricating a semiconductor device may include a hard mask includes silicon nitride, and the gate spacer includes SiOCN.

In exemplary embodiments in accordance with principles of inventive concepts, a method for fabricating a semiconductor device may include forming a fin-type active pattern that projects above a field insulating layer; forming a dummy gate structure, which includes a dummy silicon oxide layer, a poly silicon layer on the dummy silicon oxide layer including a first surface and a second surface, an epitaxial growth prevention layer which is formed on the first surface of the poly silicon layer, but is not formed on the second surface of the poly silicon layer, and a hard mask on the poly silicon layer, and which crosses the fin-type active pattern, on the fin-type active pattern; forming a gate spacer, which includes a material that is different from a material of the hard mask, on a side surface of the dummy gate structure; forming a recess in the fin-type active pattern at each side of the gate spacer; forming a semiconductor pattern in the recess using epitaxial growth; forming a trench, which crosses the fin-type active pattern, on the fin-type active pattern by removing the dummy gate structure; and forming a replacement metal gate in the trench, wherein the epitaxial growth prevention layer has high growth selectivity with respect to the epitaxial growth, so that the semiconductor pattern is not grown on the epitaxial growth prevention layer.

In exemplary embodiments in accordance with principles of inventive concepts, a method for fabricating a semiconductor device may include the first surface of the poly silicon layer is a surface that is parallel to an upper surface of the field insulating layer, and wherein the dummy gate structure is a stacked body in which the dummy silicon oxide layer, the poly silicon layer, the epitaxial growth prevention layer, and the hard mask are sequentially stacked.

In exemplary embodiments in accordance with principles of inventive concepts, a method for fabricating a semiconductor device may include the second surface of the poly silicon layer is a surface that is parallel to an upper surface of the field insulating layer, and wherein the epitaxial growth prevention layer is formed between the poly silicon layer and the gate spacer.

In exemplary embodiments in accordance with principles of inventive concepts, a method for fabricating a semiconductor device may include the epitaxial growth prevention layer is formed by thermally oxidizing a part of the poly silicon layer.

In exemplary embodiments in accordance with principles of inventive concepts, a method for fabricating a semiconductor device may include the epitaxial growth prevention layer includes at least one of silicon oxide, hafnium oxide (HfOx), aluminum oxide (AlOx), BACL (Boron doped Amorphous Carbon Layer), titanium nitride (TiN), titanium oxide (TiOx), aluminum nitride (AlN), and chrome (Cr).

In exemplary embodiments in accordance with principles of inventive concepts, a method for fabricating a semiconductor device may include forming a fin-type active pattern that projects above a field insulating layer; forming a dummy gate structure, which includes a dummy silicon oxide layer, a dummy polysilicon layer, and an epitaxial growth prevention layer that are sequentially stacked, and which crosses the fin-type active pattern, on the fin-type active pattern; forming a recess in the fin-type active pattern at each side of the dummy gate structure; forming a semiconductor pattern in the recess using epitaxial growth; forming a trench, which crosses the fin-type active pattern, on the fin-type active pattern by removing the dummy gate structure; and forming a replacement metal gate in the trench, wherein the epitaxial growth prevention layer prevents epitaxial growth on the polysilicon layer.

In exemplary embodiments in accordance with principles of inventive concepts, a method for fabricating a semiconductor device may include the epitaxial growth prevention layer is formed horizontally above the polysilicon layer.

In exemplary embodiments in accordance with principles of inventive concepts, a method for fabricating a semiconductor device may include the epitaxial growth prevention layer is formed on vertical sides of the polysilicon layer.

In exemplary embodiments in accordance with principles of inventive concepts, a method for fabricating a semiconductor device may include the formation of a polishing stopper layer over the polysilicon layer.

In exemplary embodiments in accordance with principles of inventive concepts, a method for fabricating a semiconductor device may include the formation of a barrier layer under the polysilicon layer.

### BRIEF DESCRIPTION OF THE DRAWINGS

The above and other objects, features and advantages of the present invention will be more apparent from the following detailed description taken in conjunction with the accompanying drawings, in which:

FIGS. 1 to 14 are views of intermediate steps explaining a method for fabricating a semiconductor device according to a first embodiment in accordance with principles of inventive concepts;

FIGS. 15 to 17 are views of intermediate steps explaining a method for fabricating a semiconductor device according to a second embodiment in accordance with principles of inventive concepts;

FIGS. 18 to 20 are views of intermediate steps explaining a method for fabricating a semiconductor device according to a third embodiment in accordance with principles of inventive concepts;

FIGS. 21 to 25 are views of intermediate steps explaining a method for fabricating a semiconductor device according to a fourth embodiment in accordance with principles of inventive concepts;

FIG. 26 is a block diagram of an electronic system including a semiconductor device fabricated according to embodiments in accordance with principles of inventive concepts; and

FIGS. 27 and 28 are exemplary views illustrating a semiconductor system to which a semiconductor device fabricated according to embodiments in accordance with principles of inventive concepts can be applied.

### DETAILED DESCRIPTION OF THE EMBODIMENTS

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example. may be used herein to describe various elements, components, regions, layers and/or sections, these elements, components, regions, layers and/or sections should not be limited by these terms. These terms are only used to distinguish one element, component, region, layer or section from another region, layer or section. In this manner, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. In this manner, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. In this manner, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In this manner, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments in accordance with principles of inventive concepts will be explained in detail with reference to the accompanying drawings.

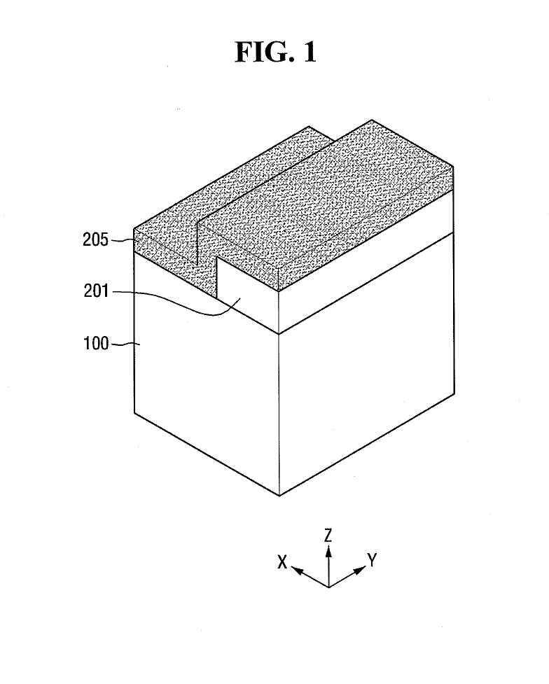

Hereinafter, referring to FIGS. 1 to 14, a method for fabricating a semiconductor device according to an exemplary embodiment in accordance with principles of inventive concepts will be described.

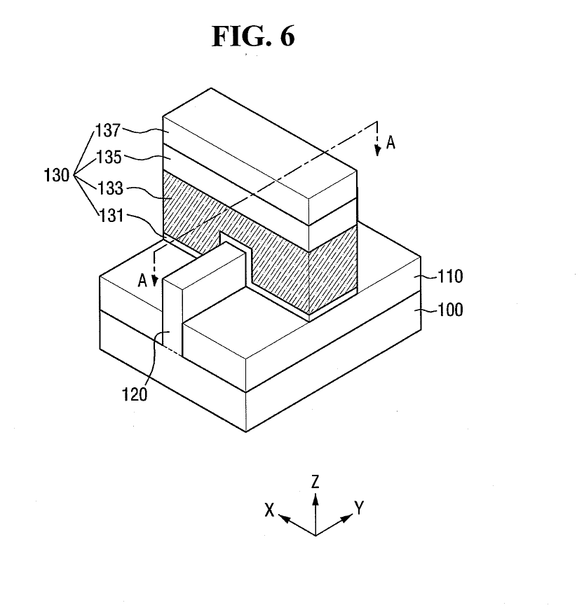

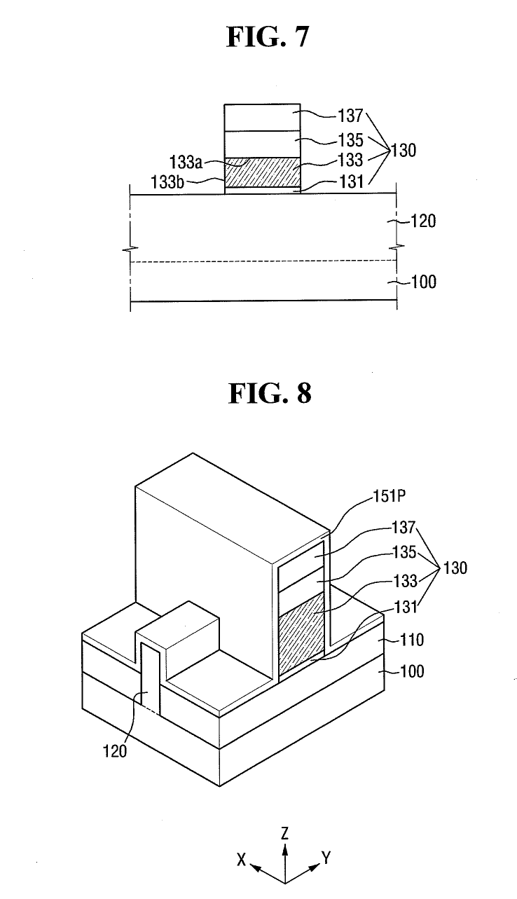

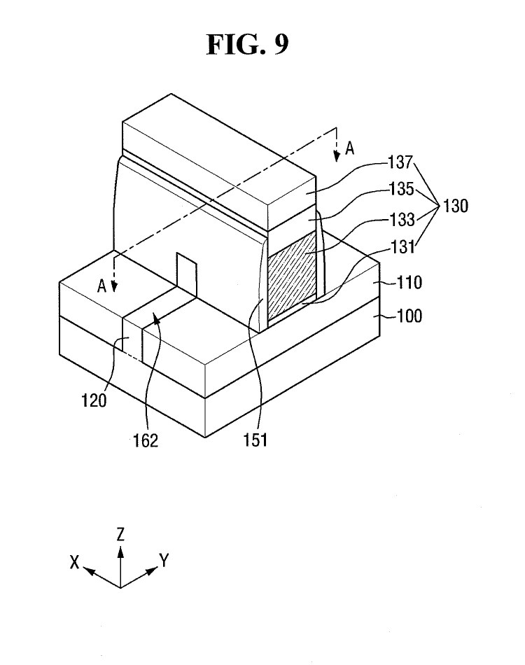

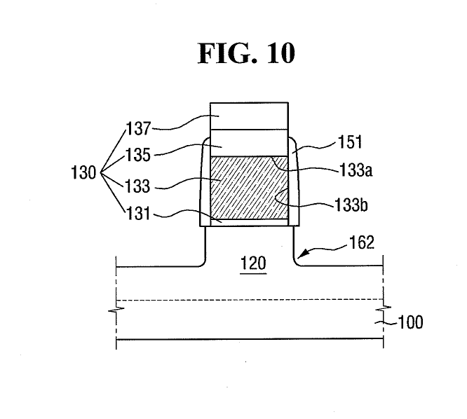

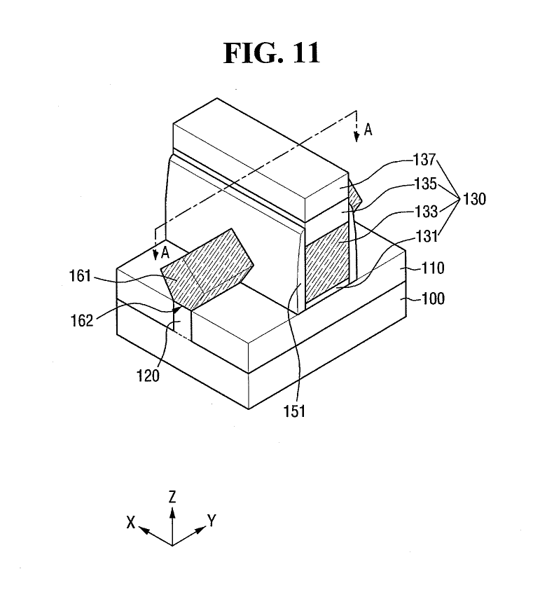

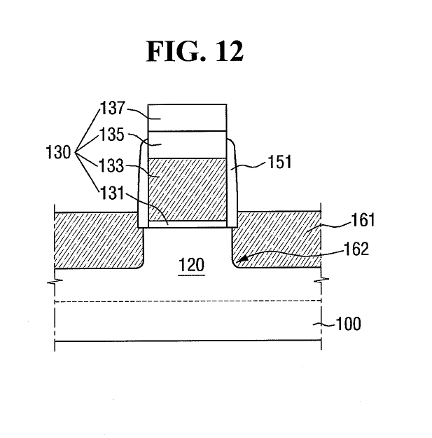

FIGS. 1 to 14 are views of intermediate steps illustrating a method for fabricating a semiconductor device according to an exemplary embodiment in accordance with principles of inventive concepts. FIG. 7 is a cross-sectional view taken along line A-A of FIG. 6, FIG. 10 is a cross-sectional view taken along line A-A of FIG. 9, and FIG. 12 is a cross-sectional view taken along line A-A of FIG. 11.

Referring to FIG. 1, a first mask pattern 201 may be formed on a substrate 100. A second mask layer 205 may be formed on the substrate on which the first mask pattern 201 is formed.

Substrate 100 may be made of, for example, bulk silicon or SOI (Silicon-On-Insulator), or may be a silicon substrate, or may include another material, for example, silicon germanium, indium antimonide, lead telluride, indium arsenide, indium phosphide, gallium arsenide, or gallium antimonide.

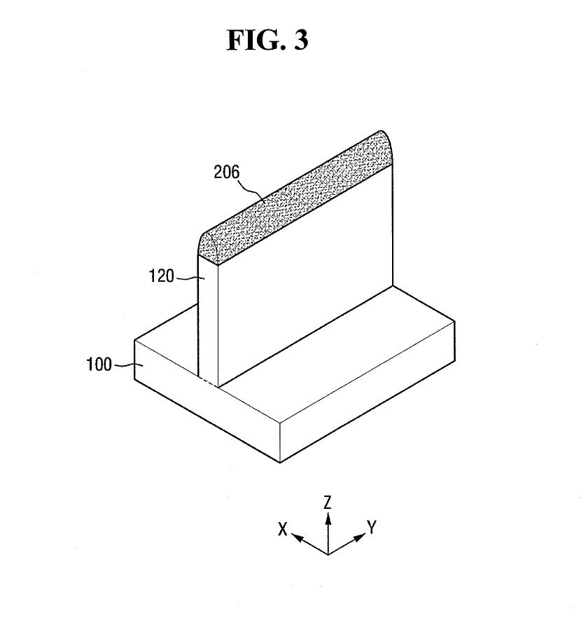

Substrate 100 may be provided by forming an epitaxial layer on a base substrate. In exemplary embodiments where a fin-type active pattern 120 as shown in FIG. 3 is formed using the epitaxial layer that is formed on the base substrate, the epitaxial layer may include silicon or germanium, which is an element semiconductor material. Additionally, the epitaxial layer may include compound semiconductor, for example, IV-IV group compound semiconductor or III-V group compound semiconductor. As an example of IV-IV group compound semiconductor, the epitaxial layer may be a binary compound, which includes at least two of carbon (C), silicon (Si), germanium (Ge), and tin (Sn), a ternary compound, or a compound that is the binary or ternary compound doped with IV group elements. As an example of III-V group compound semiconductor, the epitaxial layer may be a binary, ternary, or quaternary compound, which is formed by combining at least one of III group elements, such as aluminum (Al), gallium (Ga), and indium (In), and one of V group elements, such as phosphorous (P), arsenide (As), and antimonium (Sb).

In an exemplary method for fabricating a semiconductor device in accordance with principles of inventive concepts, it is assumed that the substrate 100 is a silicon substrate.

The second mask layer 205 may be substantially conformally formed on an upper surface of the substrate on which the first mask pattern 201 is formed. The first mask pattern 201 and the second mask layer 205 may include materials having etching selectivity with each other. For example, the second mask layer 205 may include at least one of silicon oxide, silicon nitride, silicon oxynitride, metal layer, photoresist, SOG (Spin On Glass), and SOH (Spin On Hard mask). The first mask pattern 201 may be formed of at least one of the above-described materials, which is different from the material that forms the second mask layer 205.

The first mask pattern 201 and the second mask layer 205 may be formed using at least one of PVD (Physical Vapor Deposition), CVD (Chemical Vapor Deposition), ALD (Atomic Layer Deposition), and spin coating processes, for example.

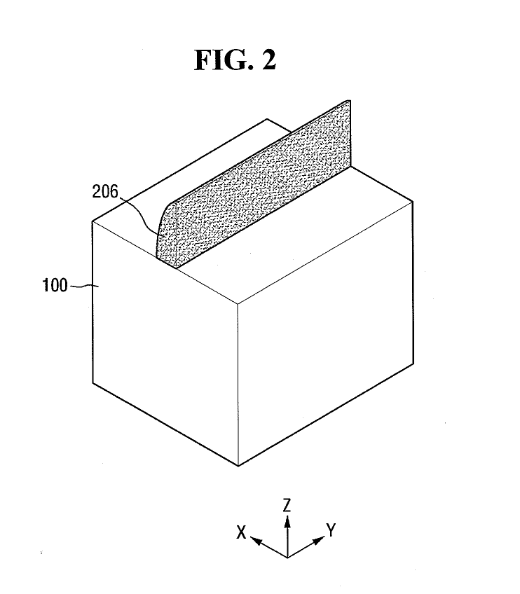

Referring to FIG. 2, a second mask pattern 206 may be formed from the second mask layer 205 in an etching process. The second mask pattern 206 may be in the form of a spacer that exposes the first mask pattern 201. As the first mask pattern 201, which is exposed by the second mask pattern 206, is removed, the substrate 100 on both sides of the second mask pattern 206 may be exposed.

The removal of the first mask pattern 201 may minimize the etching of the second mask pattern 206, and may include a selective etching process that can remove the first mask pattern 201.

Referring to FIG. 3, the substrate 100 is etched using the second mask pattern 206 as an etch mask. As a part of the substrate 100 is etched, a fin-type active pattern 120 may be formed on the substrate 100. The fin-type active pattern 120 may extend along a second direction Y. A recess is formed in the vicinity of the fin-type active pattern 120 that is formed through removal of a part of the substrate 100.

The fin-type active pattern 120 is illustrated to have a vertical slope, but is not limited thereto. That is, the side surface of the fin-type active pattern 120 may have a slope other than 90° with respect to the exposed surface of substrate 100, and thus the fin-type active pattern 120 may be in a tapered shape.

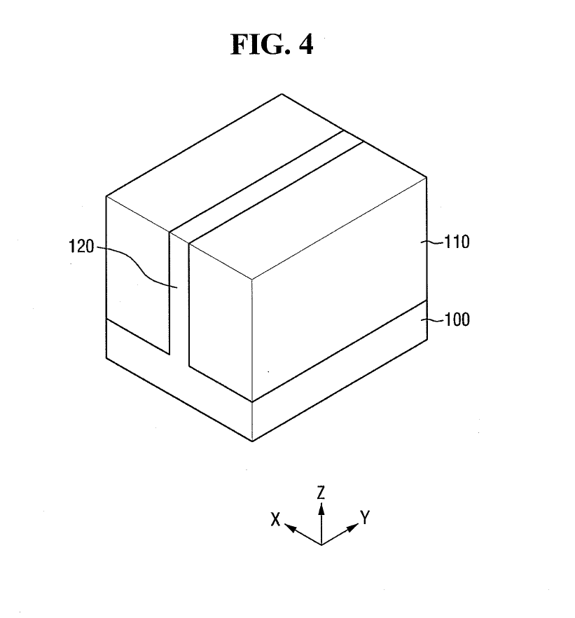

Referring to FIG. 4, a field insulating layer 110, which fills the recess, is formed in the vicinity of the fin-type active pattern 120. The field insulating layer 110 may be formed of a material such as at least one of silicon oxide, silicon nitride, and silicon oxynitride, for example.

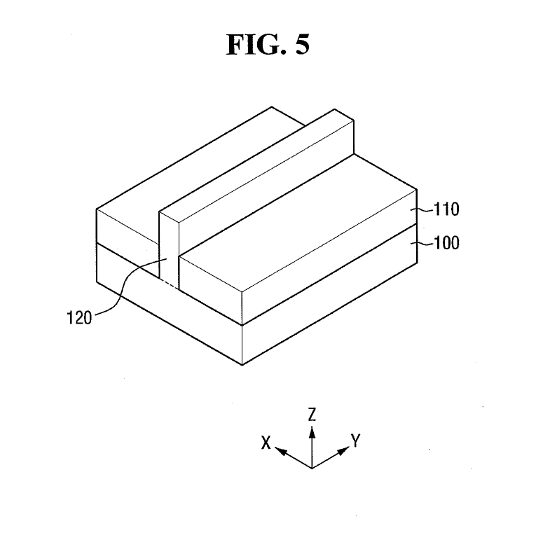

The fin-type active pattern 120 and the field insulating layer 110 may be planarized. As the planarization process is performed, the second mask pattern 206 may be removed, for example. That is, the second mask pattern 206 may be removed before the field insulating layer 110 is formed or after a recess process to be described with reference to FIG. 5 is performed, for example.

Referring to FIG. 5, by recessing an upper portion of the field insulating layer 110, an upper portion of the fin-type active pattern 120 is exposed. That is, the fin-type active pattern 120 is formed to project above the field insulating layer 110. The recess process may include a selective etching process.

On the other hand, a part of the fin-type active pattern 120 that projects above the field insulating layer 110 may be formed by an epitaxial process. Specifically, after the field insulating layer 110 is formed, a part of the fin-type active pattern 120 may be formed by an epitaxial process using an upper surface of the fin-type active pattern 120 that is exposed by the field insulating layer 110 as a seed, without performing the recess process.

Additionally, doping for adjusting a threshold voltage may be performed with respect to the fin-type active pattern 120. If a transistor that is formed using the fin-type active pattern 120 is an NMOS transistor, boron (B) may be used as an impurity. If the transistor that is formed using the fin-type active pattern 120 is a PMOS transistor, the impurity may be phosphorous (P) or arsenide (As).

Referring to FIGS. 6 and 7, a dummy gate structure 130, which crosses the fin-type active pattern 120, is formed on the fin-type active pattern 120. The dummy gate structure 130 may be formed to extend in a first direction X.

The dummy gate structure 130 includes a dummy silicon oxide layer 131, a poly silicon layer 133, an epitaxial growth prevention layer 135, and a hard mask 137, which are stacked in order. That is, the dummy gate structure 130 may be a stacked body of the dummy silicon layer 131, the poly silicon layer 133, the epitaxial growth prevention layer 135, and the hard mask 137, which extend in the first direction X.

The dummy gate structure 130 may be formed using the hard mask 137 as an etch mask.

Although in this exemplary embodiment the dummy silicon oxide layer 131 is formed not only around the fin-type active pattern 120 but also on the field insulating layer 110, the dummy silicon oxide layer 131 may be formed on only the side surface and the upper surface of the fin-type active pattern 120 that projects above the field insulating layer 110, for example, in other exemplary embodiments.

Additionally, although, in this exemplary embodiment, the dummy silicon oxide layer 131 is not formed on the fin-type active pattern 120 that does not overlap the dummy gate structure 130, the dummy silicon oxide layer 131 may be entirely formed on the side surface and the upper surface of the fin-type active pattern 120 that projects above the field insulating layer 110, for example, in other exemplary embodiments.

In exemplary embodiments in accordance with principles of inventive concepts, dummy silicon oxide layer 131 may serve to protect the fin-type active pattern 120 that is used as a channel region in a subsequent process.

The poly silicon layer 133 may be formed on the dummy silicon oxide layer 131. The poly silicon layer 133 includes a side surface 133b and an upper surface 133a, which share their corners. That is, the upper surface 133a of the poly silicon layer 133 is parallel to the upper surface of the field insulating layer 110, and the side surface 133b of the poly silicon layer 133 is parallel to a thickness direction of the substrate 100, that is, in a direction normal to the top surface of the substrate 100.

The poly silicon layer 133 may overlap the dummy gate structure 130, and may entirely cover the fin-type active pattern 120 that projects above the field insulating layer 110. That is, in exemplary embodiments in accordance with principles of inventive concepts, the height measured from the field insulating layer 110 to the upper surface of the fin-type active pattern 120 is lower than the height measured from the field insulating layer 110 to the upper surface 133a of the poly silicon layer 133.

In exemplary embodiments the poly silicon layer 133 and the dummy silicon oxide layer 130 have a high etching selectivity. Accordingly, if the poly silicon layer 133 remains on the upper surface of the fin-type active pattern 120, the poly silicon layer 133 is removed, but the lower dummy silicon oxide layer 131 remains without being etched in the following trench forming process for forming a replacement metal gate. In this manner, in accordance with principles of inventive concepts, the fin-type active pattern 120 on the lower portion of the dummy silicon oxide layer 131 can be protected.

In exemplary embodiments in accordance with principles of inventive concepts, epitaxial growth prevention layer 135 is formed on the poly silicon layer 133. Specifically, the epitaxial growth prevention layer 135 is formed on the upper surface 133a of the poly silicon layer 133, but is not formed on the side surface 133b of the poly silicon layer 133.

In exemplary embodiments in accordance with principles of inventive concepts, epitaxial growth prevention layer 135 may include materials that are different from the materials of the poly silicon layer 133 and the hard mask 137. The epitaxial growth prevention layer 135 may include a conducive material and a ceramic material, and for example, may include at least one of silicon oxide, hafnium oxide (HfOx), aluminum oxide (AlOx), BACL (Boron doped Amorphous Carbon Layer), titanium nitride (TiN), titanium oxide (TiOx), aluminum nitride (AlN), and chrome (Cr). The role of the epitaxial growth prevention layer 135 will be described in detail with reference to FIGS. 11 and 12.

The hard mask 137 is formed on the poly silicon layer 133 and the epitaxial growth prevention layer 135. The hard mask 137 may include, for example, silicon nitride (SiN), for example, but exemplary embodiments in accordance with principles of inventive concepts are not limited thereto. Additionally, the hard mask 137 may include an etch resistant material as compared with a gate spacer layer 151p to be described using FIG. 8. That is, hard mask 137 may be more etch-resistant than gate spacer layer 151p.

Referring to FIG. 8, the gate spacer layer 151p is formed to cover the fin-type active pattern 120 and the dummy gate structure 130.

The gate spacer layer 151p may be conformally formed on the side surface and the bottom surface of the dummy gate structure 130, the side surface and the bottom surface of the fin-type active pattern 120, and the field insulating layer 110.

The gate spacer layer 151p may include a low-k material, for example, such as SiOCN, but exemplary embodiments in accordance with principles of inventive concepts are not limited thereto. The gate spacer layer 151p may be formed using, for example, CVD (Chemical Vapor Deposition) or ALD (Atomic Layer Deposition).

In an exemplary method for fabricating a semiconductor device according to inventive concepts, the hard mask 137 is made of silicon nitride (SiN), and the gate spacer layer 151p is made of SiOCN. In an etching process that can simultaneously etch the hard mask 137 and the gate spacer layer 151p, the hard mask 137 may include an etch resistant material as compared with the gate spacer layer 151p.

Referring to FIGS. 9 and 10, a gate spacer 151 may be formed on the side surface of the dummy gate structure 130, and the hard mask 137 may be exposed.

Additionally, a recess 162 is formed on the side surface of the dummy gate structure 130. In exemplary embodiments in accordance with principles of inventive concepts, recess 162 is formed on the side surface of the gate spacer 151 and is formed in the fin-type active pattern 120.

The gate spacer 151 on the side surface of the dummy gate structure 130 and the recess 162 in the fin-type active pattern 120 may be simultaneously formed. That is, the gate spacer 151 may also be formed when the recess 162 is formed.

Because the gate spacer 151 is formed through etching of the gate spacer layer 151p in FIG. 8, it includes a material that is different from the material of the hard mask 137. Additionally, in exemplary embodiments in accordance with principles of inventive concepts, the hard mask 137 includes an etch resistant material as compared with the gate spacer 151. That is, hard mask 137 has greater resistance to etching than gate spacer 151.

In FIGS. 9 and 10, the height of the gate spacer 151 measured from the upper surface of the field insulating layer 110 is lower than the height measured from the upper surface of the field insulating layer 110 to the upper surface of the dummy gate structure 130, that is, the upper surface of the hard mask 137.

When the gate spacer 151 is formed on the side surface of the dummy gate structure 130, a fin spacer may be formed even on the side surface of the fin-type active pattern 120 that does not overlap the dummy gate structure 130. However, in exemplary embodiments in accordance with principles of inventive concepts, in order to form the recess 162 in the fin-type active pattern 120, the fin spacer that is formed on the side surface of the fin-type active pattern 120 may be removed. While the fin spacer that is formed on the side surface of the fin-type active pattern 120 is removed, the height of the gate spacer 151 is reduced, and a part of the hard mask is removed.

In exemplary embodiments in accordance with principles of inventive concepts, because the hard mask 137 includes the etch resistant material as compared with the gate spacer 151, the thickness of the hard mask 137 that is removed is smaller than the height of the gate spacer 151 that is removed. As a result, the height of the gate spacer 151 becomes lower than the height of the dummy gate structure 130.

FIGS. 9 and 10 illustrate that the gate spacer 151 overlaps the dummy silicon oxide layer 131, the poly silicon layer 133, and the epitaxial growth prevention layer 135 of the dummy gate structure 130, but does not overlap the hard mask 137. Additionally, as illustrated in the exemplary embodiment depicted in FIGS. 9 and 10, a part of the epitaxial growth prevention layer 135 does not overlap the gate spacer 151, but is exposed. However, this is merely for convenience in explanation, and inventive concepts are not limited thereto. That is, in accordance with etching process conditions for forming the gate spacer 151, in exemplary embodiments in accordance with principles of inventive concepts the gate spacer 151 may overlap the hard mask 137.

FIG. 10 illustrates that the fin-type active pattern 120 is undercut below the lower portions of the dummy gate structure 130 and the gate spacer 151, but exemplary embodiments in accordance with principles of inventive concepts are not limited thereto.

Referring to FIGS. 11 and 12, in exemplary embodiments in accordance with principles of inventive concepts, a semiconductor pattern 161 is formed in the recess 162 using epitaxial growth. The semiconductor pattern 161 that is formed in the recess 162 is positioned on the side surface of the dummy gate structure 130. The semiconductor pattern 161 may be a source/drain of the semiconductor device, and for example, an elevated source/drain.

By epitaxial growth, the semiconductor pattern 161 is selectively grown on the exposed fin-type active pattern 120, but the semiconductor pattern 161 is not selectively grown on the exposed epitaxial growth prevention layer 135. That is, in exemplary embodiments in accordance with principles of inventive concepts, the epitaxial growth prevention layer 135 and the exposed fin-type active pattern 120 have high growth selectivity with respect to the epitaxial growth.

In exemplary embodiments in accordance with principles of inventive concepts, high growth selectivity with respect to the epitaxial growth means that the semiconductor pattern 161 is grown on the exposed fin-type active pattern 120 that is intended to form the semiconductor pattern 161, but the semiconductor pattern 161 is not grown on the epitaxial growth prevention layer 135. Accordingly, the epitaxial grow prevention layer 135 has high growth selectivity with respect to the epitaxial growth, and as a result the semiconductor pattern 161 is not grown on the epitaxial growth prevention layer 135. If, on the other hand, growth selectivity of the epitaxial growth prevention layer were low, the semiconductor pattern grown epitaxially would form in unintended places, such as exemplified by a nodule defect, resulting in reduced process yield and reduced device performance.

If no epitaxial growth prevention layer 135 were included and the polysilicon layer were formed all the way to the bottom of the hard mask 137 a part of the poly silicon layer 133 may be exposed during epitaxial growth. In particular, a gap may be formed between hard mask 137 and gate spacer 151 and, were it not for the presence of epitaxial growth prevention layer 135, a portion of gate spacer layer 151 would be exposed during epitaxial growth. Because the poly silicon layer includes crystal planes, such as single crystal silicon, the semiconductor pattern would grow on the exposed poly silicon layer. Such parasitic growth, which may be referred to herein as a nodule defect, could reduce the performance of the associated semiconductor device and reduce process yield. Employing an epitaxial growth prevention layer 135 in accordance with principles of inventive concepts prevents such parasitic growth, eliminates nodule effect, and improves semiconductor performance and yield.

In exemplary embodiments in accordance with principles of inventive concepts, if a transistor that is formed using the fin-type active pattern 120 is a PMOS transistor, the semiconductor pattern 161 may include a compression stress material. For example, the compression stress material may be a material having higher lattice constant than Si, and may be, for example, SiGe. The compression stress material can improve mobility of carriers in a channel region through applying compression stress to the fin-type active pattern 120.

In exemplary embodiments in accordance with principles of inventive concepts, if a transistor that is formed using the fin-type active pattern 120 is an NMOS transistor, the semiconductor pattern 161 may include the same material as the substrate 100 or a tension stress material. For example, if the substrate 100 is made of Si, the semiconductor pattern 161 may include Si or a material having lower lattice constant than Si (e.g., SiC).

When the semiconductor pattern 161 is formed, an impurity may be in-situ doped in the semiconductor pattern 161 during the epitaxial process.

The semiconductor pattern 161 may have at least one of a diamond shape, a circular shape, and a rectangular shape. FIG. 11 exemplarily illustrates the semiconductor pattern in a diamond shape (or pentagonal or hexagonal shape).

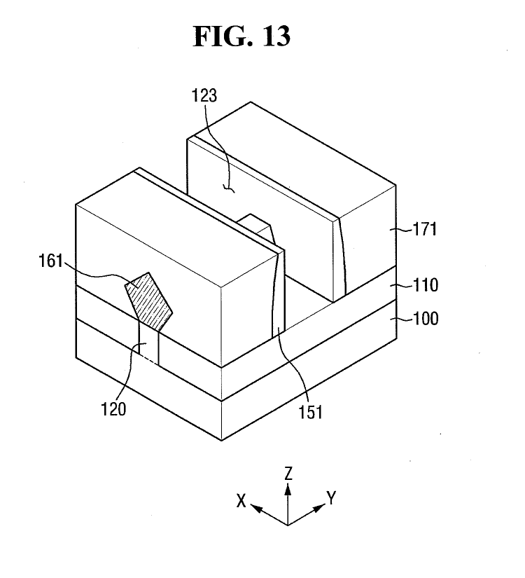

Referring to FIG. 13, an interlayer insulating layer 171, which covers the semiconductor pattern 161 and the dummy gate structure 130, is formed on the field insulating layer 110.

The interlayer insulating layer 171 may include, for example, at least one of a low-k material, an oxide layer, a nitride layer, and an oxynitride layer. The low-k material may be, for example, FOX (Flowable Oxide), TOSZ (Tonen SilaZen), USG (Undoped Silica Glass), BSG (Borosilica Glass), PSG (PhosphoSilica Glass), BPSG (BoroPhosphoSilica Glass), PRTEOS (Plasma Enhanced Tetra Ethyl Ortho Silicate), FSG (Fluoride Silicate Glass), HDP (High Density Plasma), PEOX (Plasma Enhanced Oxide), FCVD (Flowable CVD), or a combination thereof, but exemplary embodiments in accordance with principles of inventive concepts are not limited thereto.

Then, the interlayer insulating layer 171 may be planarized until the upper surface of the epitaxial growth prevention layer 135 is exposed. As a result, the hard mask 137 may be removed, and the upper surface of the epitaxial growth prevention layer 135 may be exposed. Alternatively, the interlayer insulating layer 171 may be planarized until the upper surface of the poly silicon layer 133 is exposed. As a result, the hard mask 137 and the epitaxial growth prevention layer 135 may be removed, and the upper surface of the poly silicon layer 133 may be exposed.

Then, through removal of the epitaxial growth prevention layer 135, the poly silicon layer 133, and the dummy silicon oxide layer 131, or through removal of the poly silicon layer 133 and the dummy silicon oxide layer 131, a trench 123, which crosses the fin-type active pattern 120, is formed.

That is, in exemplary embodiments in accordance with principles of inventive concepts, through removal of the dummy gate structure 130, the trench 123, which crosses the fin-type active pattern 120, is formed on the fin-type active pattern 120.

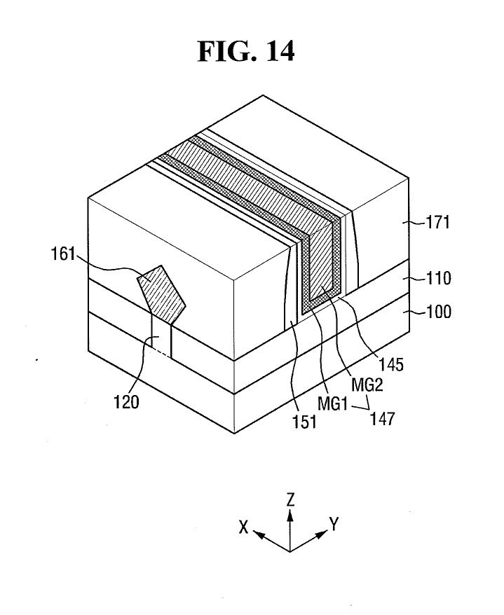

Referring to FIG. 14, a gate insulating layer 145 and a replacement metal gate 147 are funned in the trench 123.

The gate insulating layer 145 may be substantially conformally formed along the side wall and the bottom surface of the trench 123. The gate insulating layer 145 may include a high-k material having dielectric constant that is higher than the dielectric constant of the silicon oxide layer. For example, the gate insulating layer 145 may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The metal gate 147 may include metal layers MG1 and MG2. As illustrated, the metal gate 147 may include two or more stacked metal layers MG1 and MG2. The first metal layer MG1 serves to adjust a work function, and the second metal layer MG2 serves to fill a space that is formed by the first metal layer MG1. For example, the first metal layer MG1 may include at least one of TiN, TaN, TiC, and TaC. Additionally, the second metal layer MG2 may include W or Al.

Referring to FIGS. 1 to 5, and 11 to 17, a method for fabricating a semiconductor device according to a second exemplary embodiments in accordance with principles of inventive concepts, will be described. For clarity and brevity of explanation, detailed explanation of elements associated with the previous embodiment will not be repeated here.

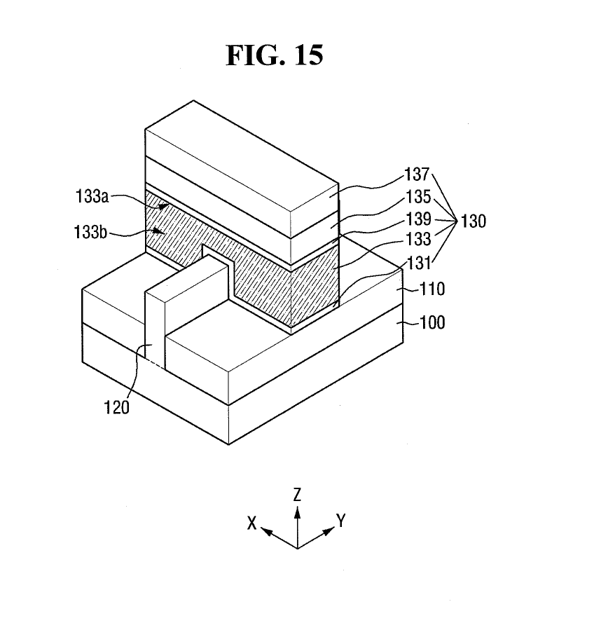

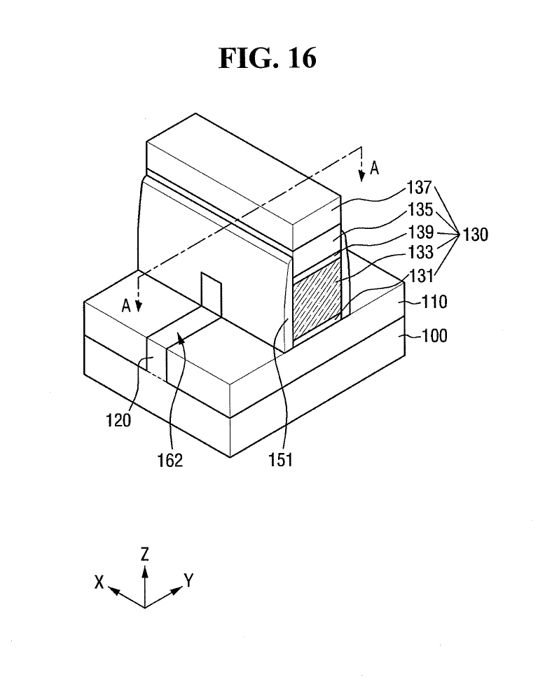

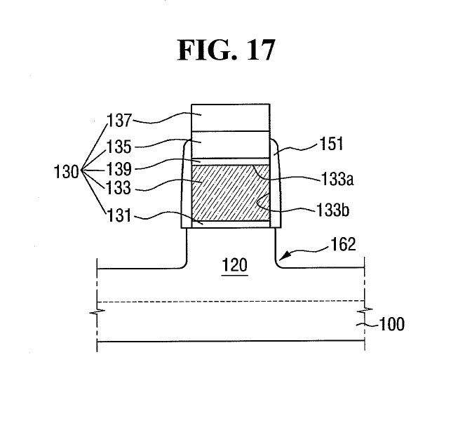

FIGS. 15 to 17 are views of intermediate steps illustrating a method for fabricating a semiconductor device according to a second exemplary embodiment in accordance with principles of inventive concepts. FIG. 17 is a cross-sectional view taken along line A-A of FIG. 16.

Referring to FIG. 15, a dummy gate structure 130 includes a polishing stopper layer 139.

The dummy gate structure 130 is formed on a fin-type active pattern 120. The dummy gate structure 130 may be formed to extend in a first direction X and to cross the fin-type active pattern 120.

A poly silicon layer 133 may be formed on a dummy silicon oxide layer 131. The poly silicon layer 133 may entirely cover the fin-type active pattern 120 that overlaps the dummy silicon oxide layer 131.

The height measured from the dummy silicon oxide layer 131 formed on an upper surface of the fin-type active pattern 120 to an upper surface 133a of a poly silicon layer may depend on the height of a replacement metal gate 147.

A polishing stopper layer 139 is formed between the poly silicon layer 133 and an epitaxial growth prevention layer 135. In exemplary embodiments in accordance with principles of inventive concepts, polishing stopper layer 139 may serve as a stopper layer in a planarization process such as a CMP (Chemical Mechanical Polishing) process.

In accordance with principles of inventive concepts, if the polishing stopper layer 139 is exposed in the planarization process of an interlayer insulating layer 171 of FIG. 13, the planarization process of the interlayer insulating layer 171 may be stopped. Additionally, if the poly silicon layer 133 is exposed through adjustment of the speed of the planarization process after the polishing stopper layer 139 is exposed, the planarization process may be stopped.

Because the polishing stopper layer 139 serves as a stopper layer to stop the planarization process of the interlayer insulating layer 171, it may include a material having a polishing selectivity with respect to the interlayer insulating layer 171. For example, if the interlayer insulating layer 171 includes silicon oxide, the polishing stopper layer 139 may include at least one of silicon nitride, hafnium oxide (HfOx), aluminum oxide (AlOx), titanium oxide (TiOx), and aluminum nitride (AlN).

Referring to FIGS. 16 and 17, a gate spacer 151 may be formed on a side surface of the dummy gate structure 130, and a hard mask 137 may be exposed. Additionally, a recess 162 is formed on a side surface of the dummy gate structure 130.

As seen in FIG. 17 in exemplary embodiments in accordance with principles of inventive concepts, the gate spacer 151 overlaps the dummy silicon oxide layer 131, the poly silicon layer 133, the polishing stopper layer 139, and an epitaxial growth prevention layer 135 of the dummy gate structure 130, but does not overlap the hard mask 137. Additionally, a part of the epitaxial growth prevention layer 135 is exposed without overlapping the gate spacer 151, but exemplary embodiments in accordance with principles of inventive concepts are not limited thereto.

Referring to FIGS. 11 to 13, a semiconductor pattern 161 is formed on the side surface of the dummy gate structure 130 using epitaxial growth. The semiconductor pattern 161 is formed in the recess 162.

Then, the interlayer insulating layer 171 is formed to cover the semiconductor pattern 161 and the dummy gate structure 130. Then, the interlayer insulating layer 171 is planarized until the polishing stopper layer 139 is exposed. As a result, an upper surface of the polishing stopper layer 139 may be exposed.

Then, a trench 123 is formed through removal of the polishing stopper layer 139, the poly silicon layer 133, and the dummy silicon oxide layer 131.

Referring to FIG. 14, a gate insulating layer 145 and a replacement metal gate 147 are formed in the trench 123. Again, employing an epitaxial growth prevention layer 135 in accordance with principles of inventive concepts prevents parasitic growth, eliminates nodule effect, and improves semiconductor performance and yield.

Referring to FIGS. 1 to 5, 11 to 14, and 18 to 20, a method for fabricating a semiconductor device according to a third exemplary embodiment in accordance with principles of inventive concepts, will be described. For clarity and brevity of explanation, detailed explanation of elements associated with the previous embodiments will not be repeated here.

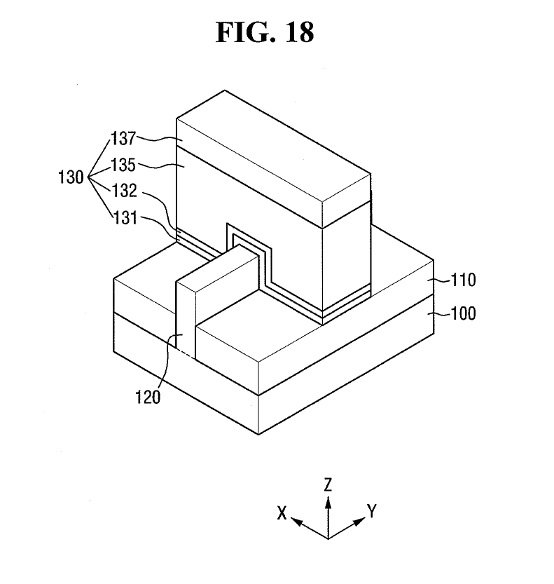

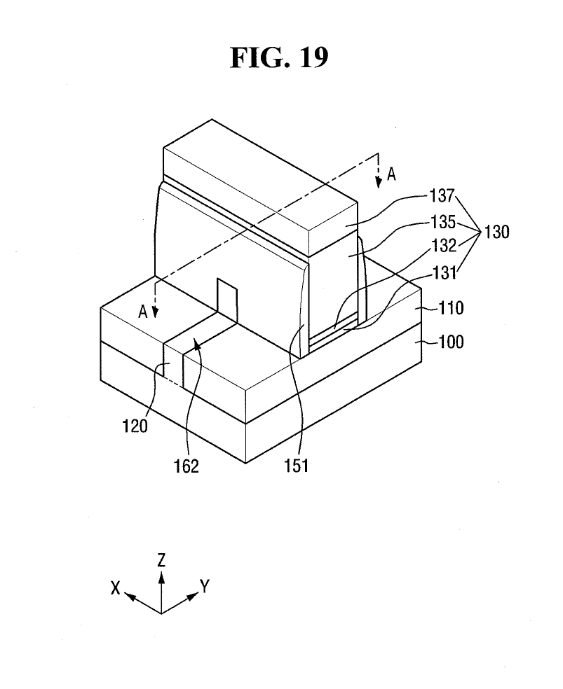

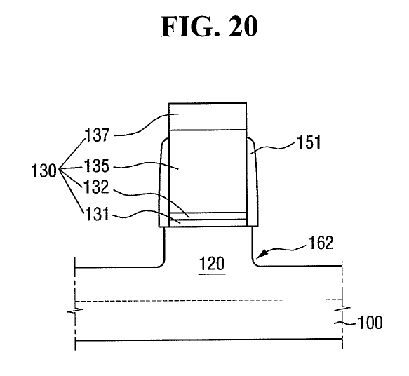

FIGS. 18 to 20 are views of intermediate steps illustrating a method for fabricating a semiconductor device according to a third exemplary embodiment in accordance with principles of inventive concepts. FIG. 20 is a cross-sectional view taken along line A-A of FIG. 19.

Referring to FIG. 18, a dummy gate structure 130 does not include a poly silicon layer 133, but includes a barrier layer 132 between a dummy silicon oxide layer 131 and an epitaxial growth prevention layer 135.

The barrier layer 132 is formed to come in contact with the dummy silicon oxide layer 131. The barrier layer 132 may be formed along a profile of the dummy silicon oxide layer 131. If the dummy silicon oxide layer 131 is not formed on the field insulating layer 110, the barrier layer 132 may be formed along the profile of the dummy silicon oxide layer 131, and may come in contact with the field insulating layer 110 and the dummy silicon oxide layer 131.

In a trench forming process such as described in the discussion related to FIG. 13, the barrier layer 132 may serve to protect the dummy silicon oxide layer 131. Accordingly, when an epitaxial growth prevention layer 135 is removed, in accordance with principles of inventive concepts the barrier layer 132 remains without being removed. In accordance with principles of inventive concepts this may be achieved by the barrier layer 132 including a material having an etching selectivity with respect to the epitaxial growth prevention layer 135. Additionally, in a process of removing the barrier layer 132, in accordance with principles of inventive concepts the dummy silicon oxide layer 131 that is under the barrier layer 132 may remain. In accordance with principles of inventive concepts, the dummy silicon oxide layer 131 may be left intact to protect fin-type active pattern 120 (to be used as a channel region) during removal of the barrier layer 132. For example, if the epitaxial growth prevention layer 135 includes silicon oxide, the barrier layer 132 may include titanium nitride (TiN), but exemplary embodiments in accordance with principles of inventive concepts are not limited thereto.

In exemplary embodiments in accordance with principles of inventive concepts, epitaxial growth prevention layer 135 is formed on the barrier layer 132. Specifically, the epitaxial growth prevention layer 135 is formed to come in contact with the barrier layer 132. The epitaxial growth prevention layer 135 may overlap the dummy gate structure 130, and may entirely cover the fin-type active pattern 120 that projects above the field insulating layer 110.

Referring to FIGS. 19 and 20, a gate spacer 151 may be formed on a side surface of the dummy gate structure 130, and a hard mask 137 may be exposed. Additionally, a recess 162 is formed on a side surface of the dummy gate structure 130.

FIG. 20 illustrates that the gate spacer 151 overlaps the dummy silicon oxide layer 131, the barrier layer 132, and the epitaxial growth prevention layer 135 of the dummy gate structure 130, but does not overlap the hard mask 137. Additionally, it is illustrated that a part of the epitaxial growth prevention layer 135 is exposed without overlapping the gate spacer 151, but exemplary embodiments in accordance with principles of inventive concepts are not limited thereto.

Referring to FIGS. 11 to 14, a semiconductor pattern 161 is formed on the side surface of the dummy gate structure 130.

Then, a replacement metal gate 147 is formed in a position from which the dummy gate structure 130 is removed. Again, employing an epitaxial growth prevention layer 135 in accordance with principles of inventive concepts prevents parasitic growth, eliminates nodule effect, and improves semiconductor performance and yield.

Referring to FIGS. 1 to 5, 11 to 14, and 21 to 25, a method for fabricating a semiconductor device according to a fourth embodiment exemplary embodiment in accordance with principles of inventive concepts, will be described. For clarity and brevity of explanation, detailed explanation of elements associated with the previous embodiments will not be repeated here.

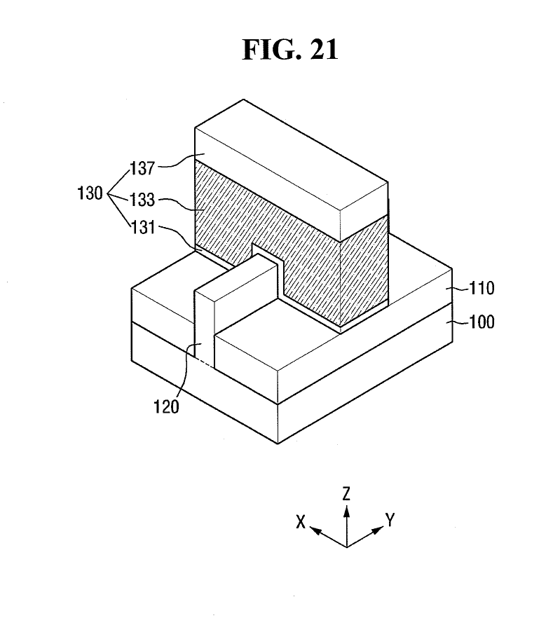

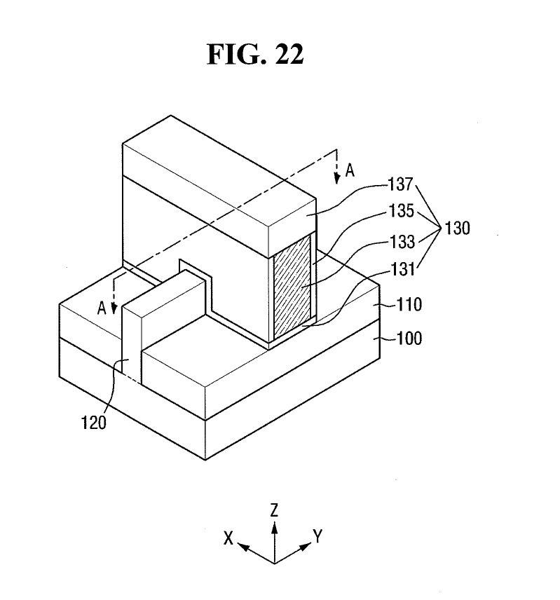

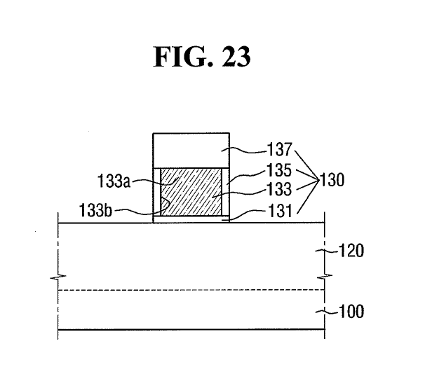

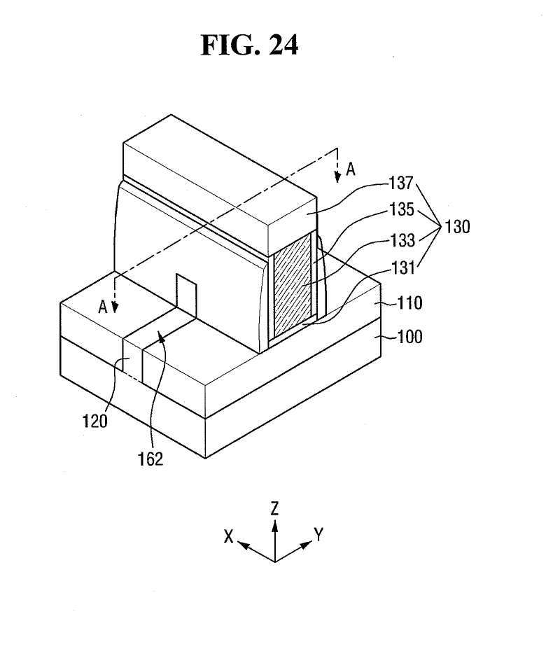

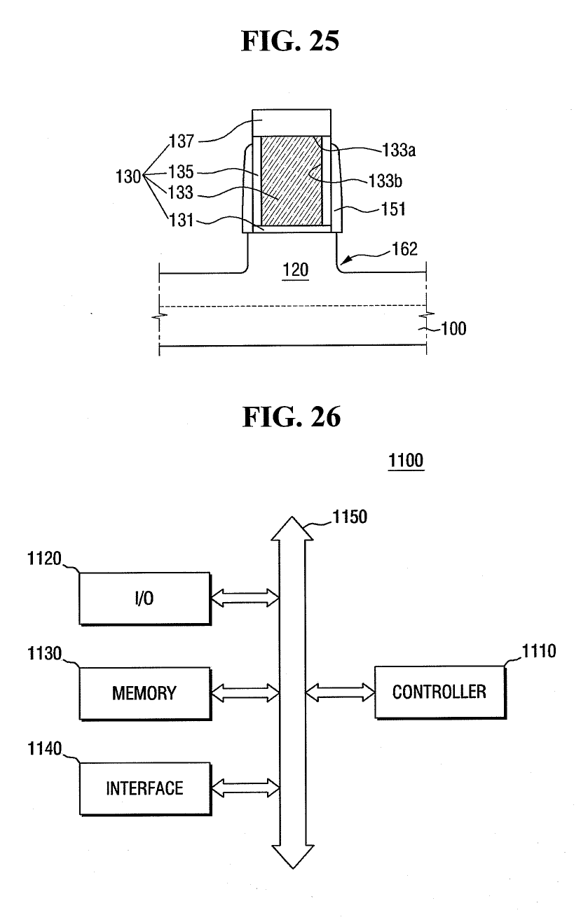

FIGS. 21 to 25 are views of intermediate steps explaining a method for fabricating a semiconductor device according to a fourth embodiment of the present invention. FIG. 23 is a cross-sectional view taken along line A-A of FIG. 22, and FIG. 25 is a cross-sectional view taken along line A-A of FIG. 24.

Referring to FIG. 21, by performing an etching process using a hard mask 137, a dummy silicon oxide layer 131 and a poly silicon layer 133, which extend in a first direction X, are formed to cross a fin-type active pattern 120.

It is illustrated that the dummy silicon oxide layer 131 is formed not only around the fin-type active pattern 120 but also on a field insulating layer 110, but exemplary embodiments in accordance with principles of inventive concepts are not limited thereto.

Additionally, it is illustrated that the dummy silicon oxide layer 131 is not formed on the fin-type active pattern 120 that does not overlap the dummy gate structure 130. However, this is merely for convenience in explanation, but the forming of the dummy silicon oxide layer 131 is not limited thereto.

Referring to FIGS. 22 and 23, a dummy gate structure 130, which crosses the fin-type active pattern 120, is formed on the fin-type active pattern 120.

An epitaxial growth prevention layer 135 is formed on a side surface 133b of the poly silicon layer 133. The epitaxial growth prevention layer 135 is not formed on an upper surface 133a of the poly silicon layer 133.

Specifically, the epitaxial growth prevention layer 135 is not formed on the upper surface 133a of the poly silicon layer that is in parallel to the upper surface 133a of the poly silicon layer 133. The epitaxial growth prevention layer 135 is formed on the side surface 133b of the poly silicon layer 133 that is in parallel to a thickness direction of the substrate 100, that is, in a direction normal to the plane of the top surface of the substrate 100.

The epitaxial growth prevention layer 135 may be formed, for example, by thermally oxidizing a part of the poly silicon layer 133. That is, the epitaxial growth prevention layer 135 may include silicon oxide, for example.

If the dummy silicon oxide layer 131 is formed on the fin-type active pattern 120 that does not overlap the dummy gate structure 130, a silicon oxide layer may not be formed on the fin-type active pattern 120 in a thermal oxidation process. In contrast, if the dummy silicon oxide layer 131 is not formed on the fin-type active pattern 120 that does not overlap the dummy gate structure 130, the silicon oxide layer may be formed on the fin-type active pattern 120 in the thermal oxidation process. However, for convenience in explanation, this is not illustrated in FIGS. 22 and 23.

A part of the dummy silicon oxide layer 131 overlaps the poly silicon layer 133, and the remainder of the dummy silicon oxide layer 131 that does not overlap the poly silicon layer 133 overlaps the epitaxial growth prevention layer 135. In the same manner, a part of the hard mask 137 overlaps the poly silicon layer 133, and the remainder of the hard mask 137 overlaps the epitaxial growth prevention layer 135.

In FIG. 23, a side surface of the dummy gate structure 130 may include the dummy silicon oxide layer 131, the epitaxial growth prevention layer 135, and the hard mask 137. Accordingly, the epitaxial growth prevention layer 135 is positioned on the side surface of the poly silicon layer 133, and the hard mask 137 and the dummy silicon oxide layer 131 are respectively positioned on the upper surface and lower surface of the poly silicon layer 133.

Referring to FIGS. 24 and 25, a gate spacer 151 may be formed on the side surface of the dummy gate structure 130, and the hard mask 137 may be exposed. Specifically, in accordance with principles of inventive concepts, the gate spacer 151 is formed on the side surface of the epitaxial growth prevention layer 135. Additionally, a recess 162 is formed on the side surface of the dummy gate structure 130.

The epitaxial growth prevention layer 135 is formed between the poly silicon layer 133 and the gate spacer 151. In other words, on the side surface 133b of the poly silicon layer 133, the epitaxial growth prevention layer 135 and the gate spacer 151 are sequentially formed around the poly silicon layer 133.

The gate spacer 151 may expose a part of the epitaxial growth prevention layer 135 and the hard mask 137.

Referring to FIGS. 11 and 12, when a semiconductor pattern 161 is formed in the recess 162, the epitaxial growth prevention layer 135 that includes silicon oxide has high growth selectivity with respect to the epitaxial growth.

Even if the epitaxial growth prevention layer 135 is exposed to precursor for the epitaxial growth during the epitaxial growth for forming the semiconductor pattern 161, the semiconductor pattern 161 is not grown on the epitaxial growth prevention layer 135, that is, on the dummy gate structure 130.

Then, a replacement metal gate 147 is formed in a position from which the dummy gate structure 130 is removed. Again, employing an epitaxial growth prevention layer 135 in accordance with principles of inventive concepts prevents parasitic growth, eliminates nodule effect, and improves semiconductor performance and yield.

FIG. 26 is a block diagram of an electronic system including a semiconductor device fabricated according to exemplary embodiments in accordance with principles of inventive concepts.

Referring to FIG. 26, an electronic system 1100 according to the embodiments of the present invention may include a controller 1110, an input/output (I/O) device 1120, a memory 1130, an interface 1140, and a bus 1150. The controller 1110, the I/O device 1120, the memory 1130, and/or the interface 1140 may be coupled to one another through the bus 1150. The bus 1150 corresponds to paths through which data is transferred.

The controller 1110 may include at least one of a microprocessor, a digital signal processor, a microcontroller, and logic elements that can perform similar functions. The I/O device 1120 may include a keypad, a keyboard, and a display device. The memory 1130 may store data and/or commands. The interface 1140 may function to transfer the data to a communication network or receive the data from the communication network. The interface 1140 may be of a wired or wireless type. For example, the interface 1140 may include an antenna or a wire/wireless transceiver. Although not illustrated, the electronic system 1100 may additionally include a high-speed DRAM and/or SRAM as an operating memory for improving the operation of the controller 1110. The fin field effect transistors according to the embodiments of the present invention may be provided inside the memory 1130 or may be provided as a part of the controller 1110 or the I/O device 1120.

The electronic system 1100 may be applied to a PDA (Personal Digital Assistant), a portable computer, a web tablet, a wireless phone, a mobile phone, a digital music player, a memory card, or any electronic device that can transmit and/or receive information in wireless environments, for example.

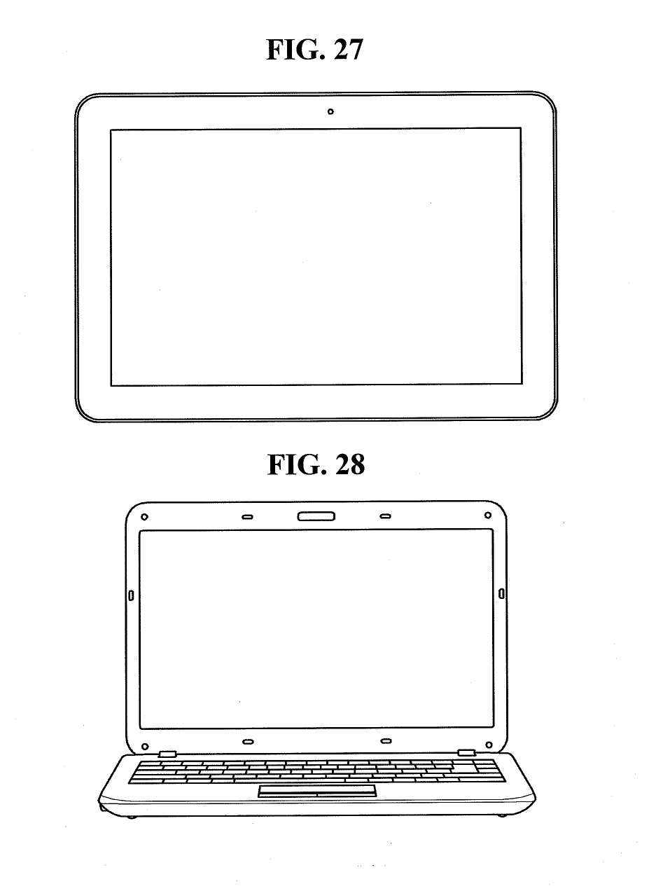

FIGS. 27 and 28 are exemplary views illustrating a semiconductor system to which a semiconductor device fabricated according to embodiments of the present invention can be applied. FIG. 27 illustrates a tablet PC, and FIG. 28 illustrates a notebook PC. The semiconductor devices fabricated according to the embodiments of the present invention may be used in the tablet PC or the notebook PC. It is apparent to those of skilled in the art that the semiconductor device fabricated according to exemplary embodiments in accordance with principles of inventive concepts of the present invention can be applied even to other integrated circuit devices that have not been exemplified.

Although preferred embodiments of the present invention have been described for illustrative purposes, those skilled in the art will appreciate that various modifications, additions and substitutions are possible, without departing from the scope and spirit of inventive concepts as disclosed in the accompanying claims.

What is claimed is:

1. A method for fabricating a semiconductor device, comprising:
forming a fin-type active pattern that projects above a field insulating layer;
forming a dummy gate structure, which includes a dummy silicon oxide layer, an epitaxial growth prevention layer, and a hard mask, that are sequentially stacked, and which crosses the fin-type active pattern, on the fin-type active pattern;
forming a recess in the fin-type active pattern at each side of the dummy gate structure;
forming a semiconductor pattern in the recess using epitaxial growth;
forming a trench, which crosses the fin-type active pattern, on the fin-type active pattern by removing the dummy gate structure; and
forming a replacement metal gate in the trench,
wherein the epitaxial growth prevention layer has high growth selectivity with respect to the epitaxial growth, so that the semiconductor pattern is not grown other than in the recess.

2. The method of claim 1, wherein the dummy gate structure further includes a poly silicon layer between the dummy silicon oxide layer and the epitaxial growth prevention layer.

3. The method of claim 2, wherein the distance between the field insulating layer and an upper surface of the fin-type active pattern is less than the distance between the field insulating layer and an upper surface of the poly silicon layer.

4. The method of claim 2, wherein the dummy gate structure further includes a polishing stopper layer between the poly silicon layer and the epitaxial growth prevention layer.

5. The method of claim 4, wherein the polishing stopper layer includes at least one of silicon nitride, hafnium oxide (HfOx), aluminum oxide (AlOx), titanium oxide (TiOX), and aluminum nitride (AlN).

6. The method of claim 1, wherein the epitaxial growth prevention layer includes at least one of silicon oxide, hafnium oxide (HfOx), aluminum oxide (AlOx), BACL (Boron doped Amorphous Carbon Layer), titanium nitride (TiN), titanium oxide (TiOx), aluminum nitride (AlN), and chrome (Cr).

7. The method of claim 6, wherein the dummy gate structure further includes a barrier layer between the dummy silicon oxide layer and the epitaxial growth prevention layer, and
wherein the barrier layer includes a material having etching selectivity with respect to the epitaxial growth prevention layer.

8. The method of claim 7, wherein the barrier layer is formed to come in contact with the dummy silicon oxide layer and the epitaxial growth prevention layer.

9. The method of claim 1, further comprising forming a gate spacer, which includes a material that is different from a material of the hard mask, on the side surface of the dummy gate structure while the recess is formed,
wherein the hard mask includes an etch resistant material as compared with the gate spacer.

10. The method of claim 9, wherein the hard mask includes silicon nitride, and the gate spacer includes SiOCN.

11. A method for fabricating a semiconductor device, comprising:
forming a fin-type active pattern that projects above a field insulating layer;
forming a dummy gate structure, which includes a dummy silicon oxide layer, a poly silicon layer on the dummy silicon oxide layer including a first surface and a second surface, an epitaxial growth prevention layer which is formed on the first surface of the poly silicon layer, but is not formed on the second surface of the poly silicon layer, and a hard mask on the poly silicon layer, and which crosses the fin-type active pattern, on the fin-type active pattern;
forming a gate spacer, which includes a material that is different from a material of the hard mask, on a side surface of the dummy gate structure;
forming a recess in the fin-type active pattern at each side of the gate spacer;
forming a semiconductor pattern in the recess using epitaxial growth;
forming a trench, which crosses the fin-type active pattern, on the fin-type active pattern by removing the dummy gate structure; and
forming a replacement metal gate in the trench,
wherein the epitaxial growth prevention layer has high growth selectivity with respect to the epitaxial growth, so that the semiconductor pattern is not grown on the epitaxial growth prevention layer.

12. The method of claim 11, wherein the first surface of the poly silicon layer is a surface that is parallel to an upper surface of the field insulating layer, and
wherein the dummy gate structure is a stacked body in which the dummy silicon oxide layer, the poly silicon layer, the epitaxial growth prevention layer, and the hard mask are sequentially stacked.

13. The method of claim 11, wherein the second surface of the poly silicon layer is a surface that is parallel to an upper surface of the field insulating layer, and
wherein the epitaxial growth prevention layer is formed between the poly silicon layer and the gate spacer.

14. The method of claim 13, wherein the epitaxial growth prevention layer is formed by thermally oxidizing a part of the poly silicon layer.

15. The method of claim 11, wherein the epitaxial growth prevention layer includes at least one of silicon oxide, hafnium oxide (HfOx), aluminum oxide (AlOx), BACL (Boron doped Amorphous Carbon Layer), titanium nitride (TiN), titanium oxide (TiOx), aluminum nitride (AlN), and chrome (Cr).

16. A method of fabricating a semiconductor device, comprising:
forming a fin-type active pattern that projects above a field insulating layer;
forming a dummy gate structure, which includes a dummy silicon oxide layer, a dummy polysilicon layer, and an epitaxial growth prevention layer that are sequentially stacked, and which crosses the fin-type active pattern, on the fin-type active pattern;
forming a recess in the fin-type active pattern at each side of the dummy gate structure;
forming a semiconductor pattern in the recess using epitaxial growth;
forming a trench, which crosses the fin-type active pattern, on the fin-type active pattern by removing the dummy gate structure; and
forming a replacement metal gate in the trench,
wherein the epitaxial growth prevention layer prevents epitaxial growth on the polysilicon layer.

17. The method of claim 16, wherein the epitaxial growth prevention layer is formed horizontally above the polysilicon layer.

18. The method of claim 16, wherein the epitaxial growth prevention layer is formed on vertical sides of the polysilicon layer.

19. The method of claim 16 further comprising the formation of a polishing stopper layer over the polysilicon layer.

20. The method of claim 16, further comprising the formation of a barrier layer under the polysilicon layer.
